(19) United States
(12) Patent Application Publication
(10) Pub. No.: US 2011/0029264 A1
(43) Pub. Date: Feb. 3, 2011

(54) OUTSIDE CONCRETE VIBRATOR HAVING AN OPERATION DISPLAY

(75) Inventor: Michael Steffen, Herrsching (DE)

Correspondence Address: BOYLE FREDRICKSON S.C., 840 North Plankinton Avenue, MILWAUKEE, WI, 53203, US

(73) Assignee: Wacker Neuson SE, Munich (DE)

(21) Appl. No.: 12/528,555

(22) PCT Filed: Feb. 18, 2008
(86) PCT No.: PCT/EP2008/001244

§ 371 Date: Sep. 27, 2010

(30) Foreign Application Priority Data
Feb. 27, 2007 (DE) 10 2007 009 508.4

(51) Int. Cl. G01R 21/00

(52) U.S. Cl. 702/60

(57) ABSTRACT

The invention relates to an outside concrete vibrator for mounting to a concrete formwork, comprising an oscillation exciter that can be driven by an electric motor, a carrier that supports the oscillation exciter and that can be mounted on the concrete formwork, and at least one electric supply line having a power supply leading to the electric motor. A detection device inductively detects a power state in the power supply. The detected power state can be displayed via an optical signal via a display device.

### BACKGROUND OF THE INVENTION

1. Field of the Invention

The present invention relates to an external concrete vibrator to be fastened to a concrete formwork.

2. Description of the Related Art

External vibrators have long been known, and as a rule are used on the outside of concrete formworks for creating concrete finished parts, in order to achieve, through the application of vibrations or vibrational forces, a required ventilation and thus compression of the still-liquid concrete in the formwork. An external vibrator usually has a relatively simple construction, and has a vibration exciter, e.g. an unbalanced shaft, that can be driven by an electric motor. The vibration exciter and the electric motor are situated on a bearer that forms the housing and that can be fastened to the concrete formwork.

Known external vibrators have an asynchronous machine that is driven at a frequency higher than the mains frequency and that sets the motor shaft and thus the unbalanced masses in the rotation, thus producing a vibration of the overall external vibrator that is transferred to the concrete formwork via the bearer. Typical external vibrators are operated with a special voltage in the range from 36 V to 250 V, and with a special electrical frequency between 50 Hz and 240 Hz. The special frequency can be provided via a motor generator, a static frequency transformer, or the like.

FIG. 6 schematically shows a side view of a concrete formwork 1 to which three known external vibrators 2 are attached as an example. Each external vibrator 2 has in its center an electric motor 3 that rotationally drives a motor shaft (not shown) to the ends of which there are fastened unbalanced masses 4. Unbalanced masses 4 and electric motor 3 are standardly covered by coverings, and are therefore not freely visible. Each electric motor 3 is supplied with power via an electrical supply cable 5. In FIG. 6, electrical supply cable 5 is represented as an example by three power supply lines 6 that are intended to depict the three phases of a three-phase drive.

Electric motor 3 and unbalanced mass 4 are accommodated in a housing that together with a bearing structure connected thereto forms a bearer 7 via which external vibrator 2 is connected to concrete formwork 1.

In most cases, the external vibrator has to be attached to the outside of the concrete formwork with great haste. For the supply of electricity, extension cables, switching boxes, and transformers are used that as a rule have an unknown electrical sense of rotation of the phases. Here, connection and functional errors may occur due to loose cables, switches that are not closed, defects, or external vibrators that are incorrectly installed or that rotate opposite a specified main direction of rotation. These mistakes are hardly recognizable for the operator, because an external vibrator does not have any moving parts that are visible from the outside. For example, it is hardly possible to recognize an external vibrator that is defective or that is not properly supplied with power in a device assembly made up of a plurality of external vibrators on a concrete formwork. However, precisely in the case of larger formworks, a large number of external vibrators must be used, such that in order to achieve an adequate working result all the external vibrators must operate in the desired manner. If one external vibrator does not operate as intended, the work result may suffer.

Depending on their function, external vibrators are often combined to form an assembly that is supplied with electricity with the aid of subdistributions, a central group cable connecting the subdistribution to, for example, a common frequency transformer. This makes it impossible to monitor the manner of operation and functioning of an individual external vibrator.

Due to the simple design and relatively low value of an external vibrator, complicated monitoring circuits are economically not practical.

### OBJECT OF THE INVENTION

The object of the present invention is to indicate an external vibrator having an individual operating display that results in only slight additional costs and is easy to use.

According to the present invention, this object is achieved by an external vibrator as recited in patent claim 1. Advantageous further developments of the present invention are defined in the dependent claims.

An external vibrator for fastening to a concrete formwork has a vibration exciter that can be driven by an electric motor, a bearer that bears the vibration exciter and that can be fastened to the concrete formwork, and an electrical supply cable, having at least one power supply line, to the electric motor. In addition, a detection device is provided for the inductive acquisition of a power state in the power supply line, and a display device is provided for displaying an optical signal that corresponds to the acquired power state.

Using the inductively acting detection device, it is possible to monitor the power supply without any special constructive measures. Rather, the external vibrator can be constructed in an otherwise known manner. The detection device can be fastened externally to the power supply line as a retrofit. Depending on the definition of the display device, the power state acquired by the detection device can then be visualized.

In this context, the power state is considered to be the presence of an electrical current (ON/OFF), the current strength, the current frequency, or the phase of the current flowing in the power supply line. In addition, as is explained in more detail below, the power state is also considered to be the relative relationship of states in a plurality of power supply lines that supply a common external vibrator. Using inductive acquisition, it is easily possible to determine these parameters.

The detection device can have an evaluation device for evaluating the acquired power state and for controlling the display device corresponding to the acquired power state in accordance with specified rules. In this way, the presence of current may be indicated, but the current strength, current frequency, or, if warranted, the current phase may also be indicated. Control lights, LEDs, etc., are suitable as a display device.

The supply cable to the electric motor can have a plurality of power supply lines, such that the detection device can inductively acquire the power states in a plurality of the power supply lines, or in all of them if warranted. The evaluation device can evaluate the respective power states, and can display them in the form of a unified, common optical signal using the display device.

In particular, in this way the evaluation device can be used to recognize the relative position of current phases of different power supply lines, and/or the presence of electrical current in all the power supply lines required for the operation of the electric motor. Accordingly, the evaluation device can first individually acquire the power states, and can then subsequently set them into relation to one another. On the basis of the relative position of the current phases, for example the direction of rotation of the electric motor can be determined. Likewise, by checking the power supply lines required for the operation of the electric motor, it can be determined whether the electric motor is sufficiently supplied with current, e.g. at all phases. This makes it possible to ensure a more reliable operation of the external vibrator that is more in line with its intended purpose.

In the evaluation device, a rule can be reproduced according to which given a particular power state in an individual power supply line, and/or given particular power states in a plurality of power supply lines, an optical signal corresponding to the rule can be displayed via the display device. In the simplest case, only the switching state (ON/OFF) is determined. On the basis of the current frequency, the rotational speed of the electric motor can also be determined. On the basis of the position of current phases of different power supply lines, the sense of rotation of the motor shaft can be determined by the evaluation device. By acquiring the current strength, an overload of the electric motor can be recognized when a boundary value is exceeded, and can be displayed if warranted using the display device.

The electrical supply cable, or power supply line, can be routed through a terminal box. The detection device can then be situated in the terminal box. Here it is to be taken into account that conventional external vibrators already standardly have a terminal box from which the electrical cable goes out. The terminal box is usually fastened directly on the bearer, or on the external vibrator housing of the bearer. The detection device can easily be situated in or on the terminal box. Because the supply lines in the terminal box are easily accessible, the inductively acting detection device can easily be realized. In particular, coils belonging to the detection device can easily be positioned on the current supply cables.

It is also possible for the electrical supply cable to have a connecting plug, and for the detection device to be situated in the connecting plug. Because the detection device does not take up much space, it is easily possible to house the detection device completely in the connecting or mains plug. The display device can also be integrated into the connecting plug; here, if warranted, a signal light or LED is to be provided in the housing of the connecting plug.

Alternatively, it is possible to situate the detection device completely in the electrical supply line, i.e. in the supply cable.

The detection device, the evaluation device, and the display device can be supplied inductively by a current that flows through the power supply lines monitored by the detection device. In this way, it is not necessary to provide an additional power supply for the devices. Rather, the current conducted to the electric motor of the external vibrator is sufficient to ensure, via inductive excitation, the supply of current and voltage to the devices. In this way, it is also very easily possible to retrofit the detection device, evaluation device, and display device without having to modify the electrical supply cable to the external vibrator, and without having to intervene in the existing system.

The display device may be provided in the vicinity of the detection device, but may also be situated at a distance therefrom. For example, the display device may be situated on the bearer in an area that is particularly easy for the operator to see.

In addition, the detection device can also be fashioned for the acquisition of a voltage state in the power supply line or in the electrical supply cable. Here, the terminal voltage can be detected galvanically, capacitively, inductively, or via a coupling element that operates in a voltage-dependent manner, such as a light source, optical coupler, etc. Thus, the terminal voltage can advantageously be acquired in contactless fashion, i.e. without direct contact with the conductors. The additional acquisition of the voltage makes it possible to determine indications of or boundary values for the power or the impedance.

Accordingly, the evaluation device can additionally be fashioned so as to evaluate the acquired voltage state, and to control the display device in a manner corresponding to the acquired voltage state. However, the evaluation of the voltage state always takes place in connection with an evaluation of the power state. The voltage determined in this way, and thus also the power, can be displayed using the display device.

These and additional advantages and features of the present invention are explained in more detail below on the basis of examples, with the aid of the accompanying Figures.

### BRIEF DESCRIPTION OF THE DRAWINGS

FIG. 1 shows the electrical supply to an electric motor in an external vibrator having an inductively operated operating display;

FIG. 2 shows another specific embodiment of the operating display;

FIG. 3 shows a further specific embodiment of the operating display;

FIG. 4 shows yet another specific embodiment of the operating display;

FIG. 5 shows another specific embodiment of the operating display; and

FIG. 6 shows a schematic diagram of the construction of a concrete formwork, with three external vibrators fastened thereto.

### DETAILED DESCRIPTION OF THE PREFERRED EMBODIMENT

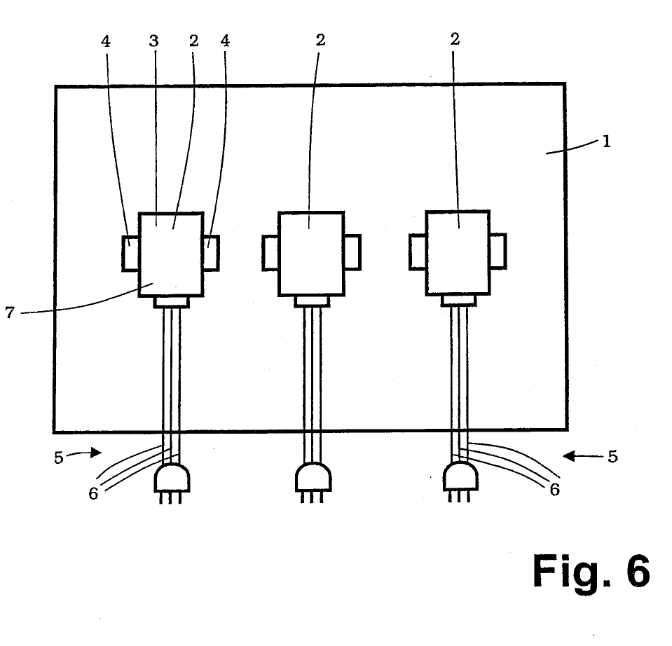

For a known external vibrator as described for example above in the basis of FIG. 6, an inductively supplied operating display is proposed. In the following, features that are also already present in a known external vibrator are provided with the same reference characters as above in FIG. 6.

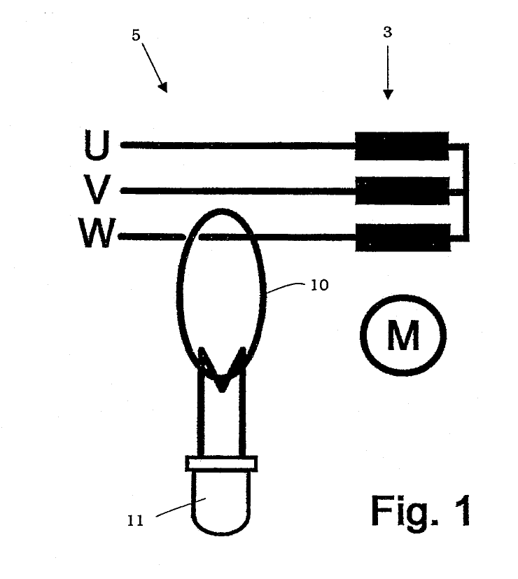

In each of FIGS. 1 through 5, an electric motor 3 is schematically shown together with an electrical supply cable 5 in which three power supply lines 6 are provided having phase designations U, V, W.

FIG. 1 shows, in a schematic representation, the three phases U, V, W, housed in the electrical cable 5 and each forming a power supply line, that are routed to electric motor 3. Power supply line W is surrounded by a coil 10 that belongs to a detection device and through which a voltage can be produced inductively. Using the voltage, a light-emitting diode 11 is operated that acts as a display device.

When a current flows through power supply line W to electric motor 3, a current is generated inductively in coil 10 that is sufficient to operate light-emitting diode 11, so that light-emitting diode 11 is illuminated. Of course, the detection device can also have additional electronic components other than coil 10 for operating and controlling light-emitting diode 11. In this way, it can easily be represented that an electrical current is flowing through power supply line W. This can of course also be realized for power supply lines U and V.

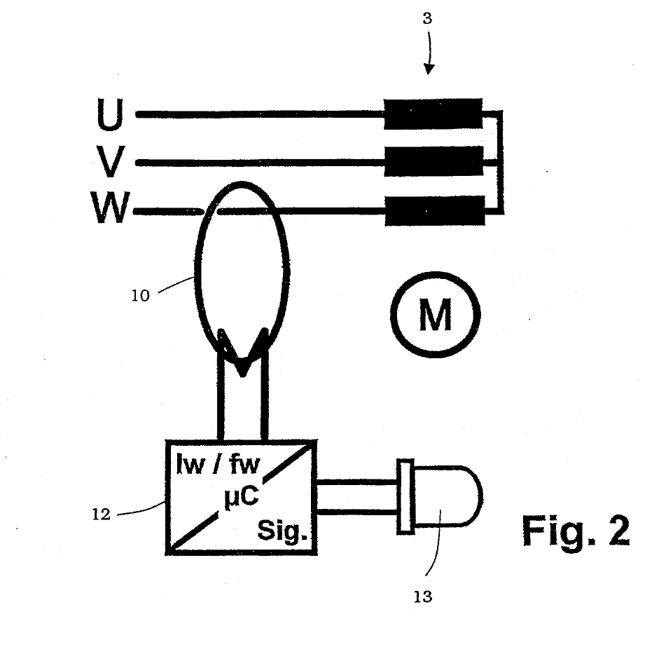

FIG. 2 shows a different embodiment, in a simplified representation. Here, the detection device has, in addition to coil 10, a microprocessor 12 that acts as evaluation device 12. Using microprocessor 12, it is possible to determine not only the presence of current in power supply line W. Using the frequency of the phase in power supply line W, it is additionally possible to determine the control frequency for electric motor 3 and to represent it via a display device 13. Display device 13 can likewise be one or more light-emitting diodes 11. Depending on the program or operating rule stored in microprocessor 12, display device 13 can be operated when a prespecified nominal frequency is achieved. In this way, it can be displayed for example whether electric motor 3 has a rotational speed in the specified nominal range or outside the nominal range.

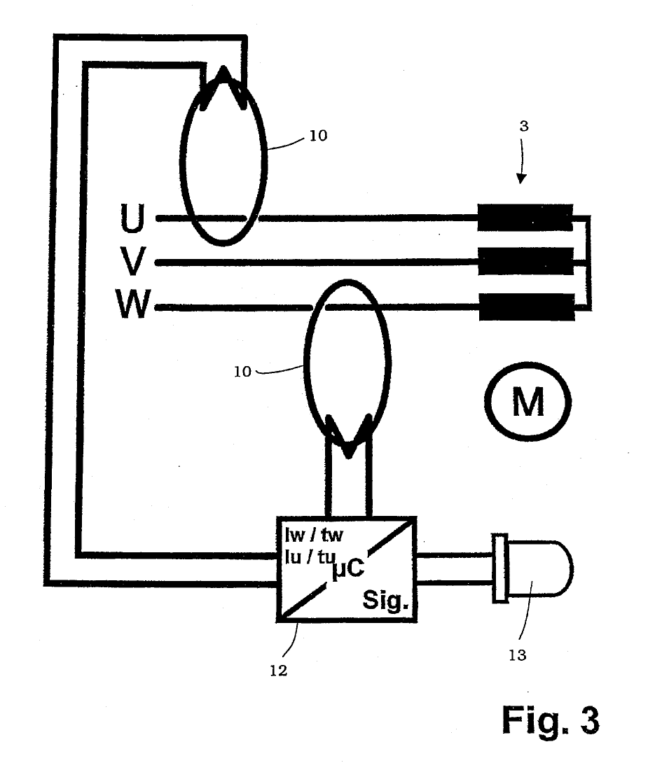

FIG. 3 shows another specific embodiment in which two power supply lines, namely power supply lines U and W, are monitored using coils 10 and a microprocessor 12. Here as well, coil 10 and microprocessor 12 form the detection device. In this way, it is possible not only to determine the presence of an electrical current in the two power supply lines U, W; in addition it is also possible to acquire the motor phases in power supply lines U, W and to set them into temporal relation to one another. On the basis of the ratio of the individual phases, the sense of rotation of the motor shaft in electric motor 3 can be determined. Correspondingly, display device 13 can be operated in order for example to indicate the direction of rotation of the motor shaft, or the correct sense of rotation of the motor shaft.

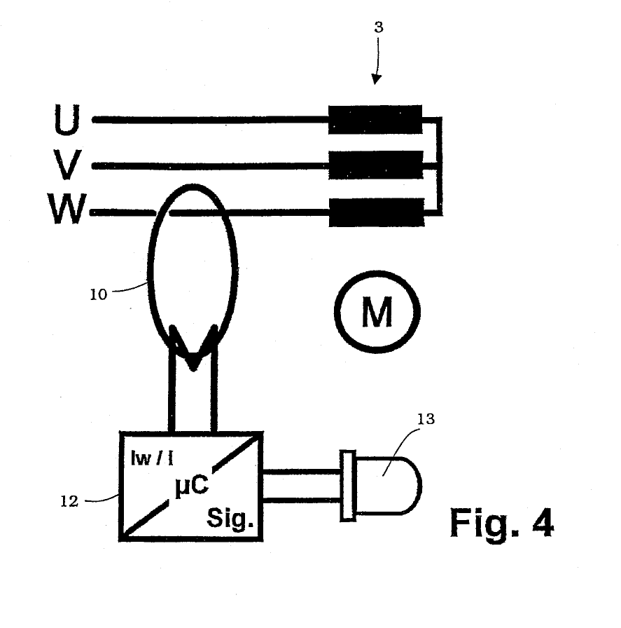

FIG. 4 shows another specific embodiment in which, using microprocessor 12, the current strength is acquired in power supply line W and is compared to a prespecified nominal or standard value. If the actual current value, acquired using coil 10, corresponds to the nominal value within permissible limits of tolerance, display device 13 can provide outward documentation of this fact. However, display device 13 can also make known an impermissible deviation. For this purpose, for example a light-emitting diode that is part of display device 13 can be made to blink. In this way, the operator is informed that the electrical loading in power supply line W is too great or too small. It is also possible in this way to realize an overload or error indication.

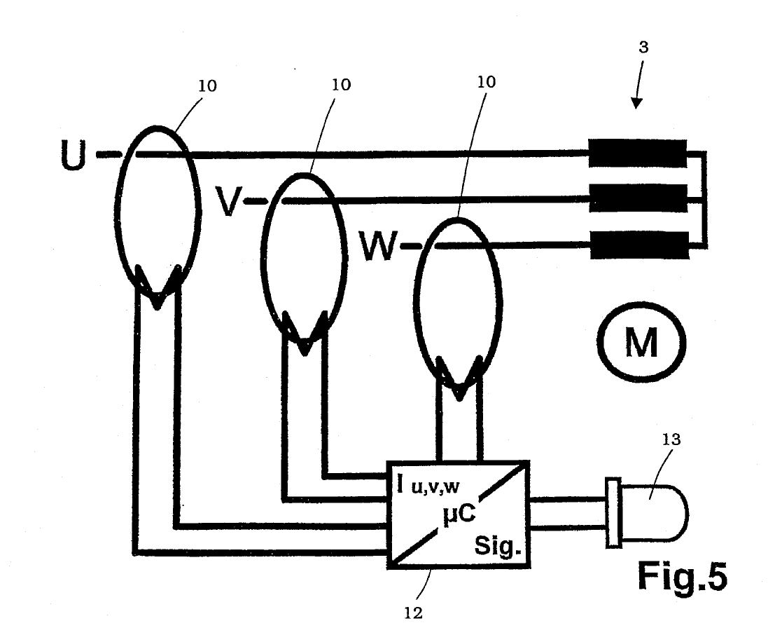

FIG. 5 shows another specific embodiment in which the presence of all motor phases U, V, W is acquired using three coils 10. Microprocessor 12 evaluates the signals from coils 10 and can in this way determine that current is actually flowing through all power supply lines U, V, W. A corresponding signal can then be outputted via display device 13.

In all the described exemplary embodiments, the supply of voltage to the detection device, i.e. to coils 10 and to microprocessor 12, is achieved using the current that is induced in coils 10. The voltage required for the operation of display device 13 is also provided in this way. Thus, neither detection device 10, 12 nor display device 13 or light-emitting diode 11 require a separate voltage supply.

In the exemplary embodiments, in some cases only one power supply line was evaluated. Of course, it is also possible to acquire other, or all, power supply lines U, V, W and to evaluate them.

In the simplest case, the operator of the external vibrator according to the present invention is provided with an indication of operational readiness, and thus with a simple way of monitoring the functioning of the external vibrator. Depending on the construction of the system, it is also possible to display the direction of rotation of the external vibrator, and to indicate equipment and power supply errors that may occur.

We claim:

1. An external vibrator for fastening to a concrete formwork comprising:
a vibration exciter that can be driven by an electric motor;
a bearer that bears the vibration exciter and that is fastened to the concrete formwork; and
an electrical supply cable, having at least one power supply line, connected to the electric motor;
a detection device that intuitively acquires a power state in the power supply line; and
a display device that displays an optical signal corresponding to the acquired power state.

2. The external vibrator as recited in claim 1, wherein the power state is a parameter selected from the group consisting of:
presence of an electrical current;
current strength;
current frequency; and
current phase.

3. The external vibrator as recited in claim 1, wherein the detection device has an evaluation device that evaluates the acquired power state and that controls the display device corresponding to the acquired power state.

4. The external vibrator as recited in claim 3, wherein:
the supply cable has a plurality of power supply lines;
the detection device inductively acquires the power states in a plurality of the power supply lines; and
the respective power states are evaluated by the evaluation device and are displayed by the display device in the form of a unified optical signal.

5. The external vibrator as recited in claim 3, wherein the evaluation device recognizes at least one of:
the relative position of current phases of different power supply lines; and
the presence of electrical current in all the power supply lines required for the operation of the electric motor.

6. The external vibrator as recited in claim 3, wherein, in the evaluation device, a rule is reproduced according to which given a particular power state in an individual power supply line and/or given particular power states in a plurality of power supply lines, and wherein an optical signal corresponding to the rule is displayed via the display device.

7. An external vibrator as recited in claim 1, wherein:
the electrical supply line is routed through a terminal box; and wherein
the detection device is situated in the terminal box.

8. The external vibrator as recited in claim 7, wherein the terminal box is fastened to the bearer.

9. The external vibrator as recited in claim 1, wherein:
the electrical cable has a connecting plug, and wherein
the detection device is situated in the connecting plug.

10. The external vibrator as recited in claim 1, wherein the detection device is situated completely in the electrical cable.

11. The external vibrator as recited in claim 1, wherein the detection device, the evaluation device, and the display device are supplied inductively by a current that flows through the power supply line that is monitored by the detection device.

12. The external vibrator as recited in claim 1 wherein the display device is provided on the bearer.

13. The external vibrator as recited in claim 1 wherein the detection device additionally acquires a voltage state in at least one of the power supply line and the electrical supply cable.

14. The external vibrator as recited in claim 13, wherein the evaluation device additionally evaluates the acquired voltage state and controls the display device corresponding to the acquired voltage state.
